(19) United States
(12) Patent Application Publication
(10) Pub. No.: US 2004/0098655 A1
(43) Pub. Date: May 20, 2004

(54) Rolling CRC scheme for improved error detection

(76) Inventor: Debendra Das Sharma, Santa Clara, CA (US)

Correspondence Address: HEWLETT-PACKARD COMPANY, Intellectual Property Administration, P.O. Box 272400, Fort Collins, CO, 80527-2400, US

(21) Appl. No.: 10/300,443

(22) Filed: Nov. 19, 2002

(51) Int. Cl. H03M 13/00

(52) U.S. Cl. 714/758

(57) ABSTRACT

A method and apparatus of communicating data, such as in a sending node or a receiving node of a networked system, includes generating a cyclic redundancy code (CRC) for at least one data block of a series of data blocks. The CRC is a function of the at least one data block and a preceding data block.

### THE FIELD OF THE INVENTION

The present invention relates generally to data communication systems, and more particularly to networked systems transmitting data between distributed nodes and employing error detection techniques to determine whether transmitted data is received free of error.

### BACKGROUND OF THE INVENTION

Networked systems transmit data between distributed nodes via some form of network connection. Unfortunately, these network connections are often noisy and sometimes introduce errors to the transmitted data. In response, many error detection techniques have been developed, all of which operate by enabling a receiver of data transmitted through an network connection to determine whether the data was received free of error.

In one general error detection technique, a transmitter in a sending node, calculates a value called a checksum from the data to be transmitted and then appends the checksum to the end of the data to be transmitted. The data, along with its associated checksum, is then transmitted from the sending node to a receiver in a receiving node. The receiver in the receiving node then calculates the checksum from the received data block in the same manner it was calculated by the sending node. The checksum calculated by the receiving node matching the checksum appended to the transmitted data by the sending node, indicates that the data block was received free of error.

One conventional error detection application employing this general error detection technique involves the use of cyclic redundancy code (CRC) schemes. In a CRC error detection scheme, the data to be transmitted is viewed as a large binary number which is divided by another binary number, referred to as a generator polynomial. The remainder from this division is the CRC checksum, generally referred to as simply the CRC, which is then appended to the data prior to transmission. The degree of the generator polynomial equals the number of bits of the CRC to be appended to the data to be transmitted.

The degree of error detection capability provided by a CRC error detection scheme is proportional to the degree of the generator polynomial utilized by the CRC scheme. The higher the degree of the generator polynomial, the higher the capability of error detection. Thus, one approach used to improve the error detection capability of a CRC scheme is to increase the degree of the generator polynomial. However, as a consequence of increasing the degree of the generator polynomial, the number of bits allotted to the CRC also increases, which reduces the effective available bandwidth of the network connection and increases the time required to transmit data between nodes. Moreover, in some networked systems, the width of the network connection may be difficult to increase for various reasons, such as due to cost, electrical constraints, and/or limited access to higher bandwidth network connections. When transmitting critical data where improved error detection would be desirable, these systems utilizing a CRC error detection technique face the design choice of improving error detection at the expense of effective available bandwidth or maintaining effective available bandwidth at the expense of potentially inadequate error detection.

Many systems, particularly those having bandwidth constraints, would benefit from a CRC error detection system that provides improved error detection without requiring an increase in the number of bits allotted for the CRC checksum or an increase in the network connection bandwidth.

### SUMMARY OF THE INVENTION

One aspect of the present invention provides method of communicating data. The method includes generating a cyclic redundancy code (CRC) for at least one data block of a series of data blocks. The CRC is a function of the at least one data block and a preceding data block.

One aspect of the present invention provides a sending node including an encoder configured to receive a series of data blocks and to provide for at least one data block of the series an expected cyclic redundancy code (CRC). The expected CRC is a function of the at least one data block and a preceding data block.

One aspect of the present invention provides a receiving node including a decoder configured to receive a series of data blocks and an expected cyclic redundancy code (CRC) for at least one block of the series and to provide for the at least one data block a calculated CRC. The calculated CRC is a function of the at least one data block and a preceding data block. The receiving node also includes a comparator configured to compare the calculated CRC to the expected CRC for the at least one data block to thereby provide an indication of whether a data error is present in the at least one data block or the preceding data block.

One aspect of the present invention provides a networked system comprising a network connection, a sending node coupled to the network connection, and a receiving node coupled to the network connection. The sending node includes an encoder configured to receive a series of data blocks and to provide for at least one data block of the series an expected cyclic redundancy code (CRC) that is a function of the at least one data block and a preceding data block. The receiving node includes a decoder configured to receive from the sending node the series of data blocks and the expected CRC for the at least one data block of the series and to provide for the at least one data block a calculated CRC that is a function of the at least one data block and the preceding data block. The receiver also includes a comparator configured to compare the calculated CRC to the expected CRC for the at least one data block to thereby provide an indication of whether a data error is present in the at least one data block or the preceding data block.

### BRIEF DESCRIPTION OF THE DRAWINGS

FIG. 1 is a block diagram of a networked system.

FIG. 2A is an illustrative diagram of an example packetized message configuration for physically transmitting data messages in a networked system.

FIG. 2B is an illustrative diagram of an example flit configuration.

FIG. 3 is a block diagram illustrating one embodiment of a rolling CRC error detection scheme according to the present invention.

FIG. 4 is a block diagram of one embodiment of networked system according to the present invention.

FIG. 5 is a block diagram of one embodiment of a sending node according to the present invention.

FIG. 6 is a block diagram of one embodiment of a receiving node according to the present invention.

### DESCRIPTION OF THE PREFERRED EMBODIMENTS

In the following detailed description of the preferred embodiments, reference is made to the accompanying drawings, which form a part hereof, and in which is shown by way of illustration specific embodiments in which the invention may be practiced. It is to be understood that other embodiments may be utilized and structural or logical changes may be made without departing from the scope of the present invention. The following detailed description, therefore, is not to be taken in a limiting sense, and the scope of the present invention is defined by the appended claims.

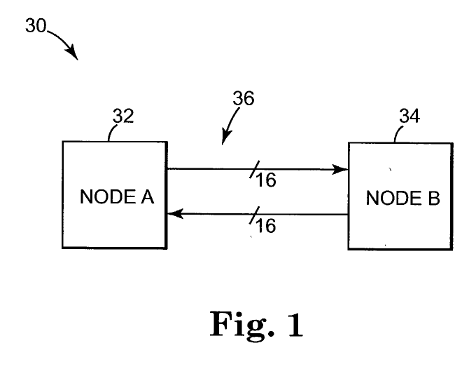

A networked system is illustrated generally at 30 in block diagram form in FIG. 1. Networked system 30 includes a node A indicated at 32 and a node B indicated at 34. Networked system 30 has the implicit ability to communicate data between node A indicated at 32 and a node B indicated at 34 via an network connection 36. However, network connections are often noisy and can introduce errors that can corrupt transmitted data. As a result, various error detection schemes have been developed to allow a node receiving data transferred through the network connection to determine whether the data was received free of error.

As discussed in the Background of the Invention section of the present specification, one such conventional error detection scheme generally adopted by networked systems is a cyclic redundancy code (CRC)) error detection scheme. In a CRC error detection scheme, the data to be transmitted is viewed as a large binary number. The node sending the data divides the large binary number formed by the data by a second binary number, referred to as a generator polynomial. The remainder from this division operation is referred to as the CRC checksum, typically referred to as simply the CRC. The sending node then appends the CRC to the data and transmits the data and the appended CRC to a receiving node via an network connection. Upon receiving the transmitted data and CRC, the receiving node calculates the CRC from the received data using the same generator polynomial as the sending node. The CRC calculated by the receiving node from the received data matching the CRC transmitted by the sending node indicates that the transmitted data was received free of error.

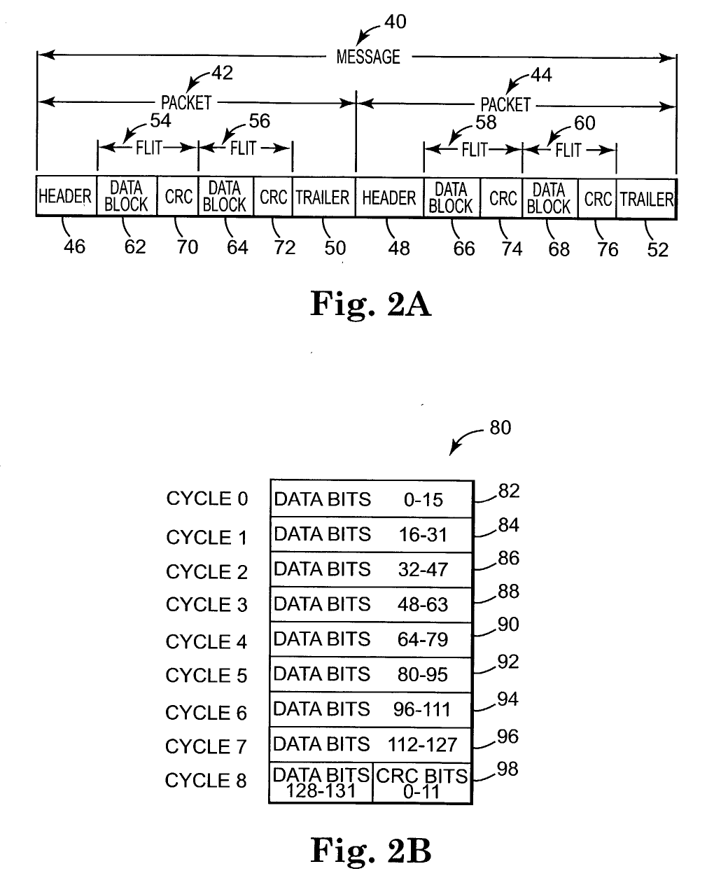

FIGS. 2A is an illustrative diagram of an example message configuration 40 for physically transmitting data between network system nodes, such as between node A indicated at 32 and node B indicated at 34 of networked system 30. Data is typically communicated between nodes in the form of a message, such as represented by message configuration 40. A message is herein defined to be an application-defined unit of data exchange between nodes. Messages are typically organized in packets, such as packets 42 and 44, for physically transmitting the message between nodes. A packet is herein defined to be a unit of data encapsulated between a network protocol header and/or trailer, such as headers 46 and 48, and trailers 50 and 52. Each packet further comprises units of data, herein referred to as flits, as indicated by flits 54, 56, 58, and 60. Finally, each flit comprises a data block, as indicated by 62, 64, 66, and 68, and a CRC, as indicated by 70, 72, 74, and 76.

FIG. 2B is an illustrative diagram of an example flit configuration 80 for networked system 30 of FIG. 1. In the illustrative example configuration of FIG. 2B, flits 80 for networked system 30 each comprise a data block of 132 bits and a CRC of 12 bits, and node A indicated at 32 and node B indicated at 34 can transmit 16 bits of data per cycle via network connection 36. The present invention described below can, however, apply to any suitable flit configuration, data block size, CRC size, and data transfer rate. In the illustrative example of FIG. 2B, nine cycles are required for node A indicated at 32 to transmit flit 80 to node B indicated at 34. Thus, for example flit 80, data bits 0-15 indicated at 82 are transmitted at cycle 0; data bits 16-31 indicated at 84 are transmitted at cycle 1; data bits 32-47 indicated at 86 are transmitted at cycle 2; data bits 48-63 indicated at 88 are transmitted at cycle 3; data bits 64-79 indicated at 90 are transmitted at cycle 4; data bits 80-95 indicated at 92 are transmitted at cycle 5; data bits 96-111 indicated at 94 are transmitted at cycle 6; data bits 112-127 indicated at 96 are transmitted at cycle 7; and data bits 128-131 and CRC bits 0-11 indicated at 98 are transmitted at cycle 8.

The generator polynomials of CRC error detection schemes are modulo primitive polynomials, where the degree of the module primitive polynomial is the same as the number of bits allotted for the CRC. Thus, for example flit 80 of FIG. 2B, the generator polynomial would be a modulo primitive polynomial of degree 12. The degree of error detection capability provided by conventional CRC schemes is proportional to the degree of the generator polynomial. Thus, as more CRC bits are utilized, the degree of the generator polynomial increases resulting in better error detection capability. In general, the probability that random multi-bit errors will be undetected can be expressed by the following Equation I:

Probability of Undetected Multi-Bit Error=2⁽⁻ⁿ⁾ where n=the number of allotted CRC bits per flit. Equation I

When applying the above Equation I to the illustrative example flit configuration 80 of FIG. 2B for networked system 30, the probability that random multi-bit errors will go undetected when transmitting flit 80 from node A indicated at 32 to node B indicated at 34 via network connection 36 is 1/4096. Whether this undetected multi-bit error probability is an acceptable level of error detection depends on the error rate and the targeted silent corruption rate.

To provide improved error detection when the silent data corruption probability is higher than can be tolerated, two conventional approaches have been used to improve error detection capability. A first conventional approach is to increase the degree of the modulo primitive polynomial used for the CRC generator polynomial. For instance, when using example flit configuration 80 for networked system 30, increasing the generator polynomial from a degree of 12 to a degree of 16 improves the probability of undetected multi-bit error from 1/4096 to 1/65,536. However, as a result of increasing the degree of the generator polynomial, the number of bits allotted to the CRC also increases. As a consequence, the number of data bits capable of being transferred by example flit 80 is reduced, which ultimately reduces the effective bandwidth of network connection 36 and increases the time required for node A indicated at 32 to transfer a given amount of data to node B indicated at 34.

A second conventional approach is to utilize a packet-level CRC in addition to the flit-level CRC. In this approach, the data blocks of the flits in a packet are combined to form a large binary number which is then divided by a second generator polynomial to produce the packet-level CRC. While this second conventional approach provides improved error detection capabilities with a negligible reduction in bandwidth, it has the disadvantage of introducing latency into the system as a result of having to wait to receive all the data blocks that form the packet before determining whether the packet was corrupted during transmission.

The below described rolling CRC error detection scheme of the present invention can provide improved error detection capabilities without decreasing the effective bandwidth between the sending and receiving nodes and without the latency involved with having to wait for all of the data blocks of a packet before determining whether to use the data blocks that form the packet. In one embodiment, the below described rolling CRC error detection scheme of the present invention provides improved error detection capability by having the CRC of at least one data block in at least one corresponding transmitted flit serve not only as an error check for the at least one data block of the corresponding flit, but also for the data blocks of one or more flits preceding the at least one data block in transmission through the network connection. The number of preceding flits for which the CRC of a given flit serves as an error check is defined herein as its depth. For example, the CRC of a given flit which also serves as an error check for two flits preceding the given flit in transmission through the network connection has a depth of two, while the CRC of a given flit serving as an error check for one preceding flit has a depth of one. In one embodiment, the depth is user and/or application selectable.

By affecting the CRC of a given data block b by preceding data blocks b-1 through b-x, a rolling CRC scheme according to the present invention identifies that there was a data error in one of these data blocks. Thus, the probability that random multi-bit errors will be undetected decreases and can be expressed by the following equation II:

Probability of Undetected Multi-Bit Error=2^{(-n(x+1))} Equation II

where:

n=the number of allotted CRC bits per flit; and

x=the CRC depth (i.e., the number of preceding data blocks).

An error detected in data block b indicates that potential data corruption exists in data blocks b through b-x. In one example embodiment, all data blocks in this range of potential data corruption would be discarded.

However, this does not mean that a node receiving transmitted data must wait to begin processing an already received data block until all subsequent data blocks whose CRC rely upon it are received. A typical routing circuit, such as implemented in an integrated circuit, has an inherent latency arising from processing and forwarding logic that will often exceed any latency created by the rolling CRC error detection scheme in waiting to receive subsequent data blocks whose CRCs rely on an already received data block, especially when the CRC depth is not extreme. Thus, if an error is detected after receiving all subsequent data blocks whose CRC depends on a data block already being processed by the receiving node, all of the data blocks in the range can be discarded and flushed from the pipeline before the receiving node relies upon them.

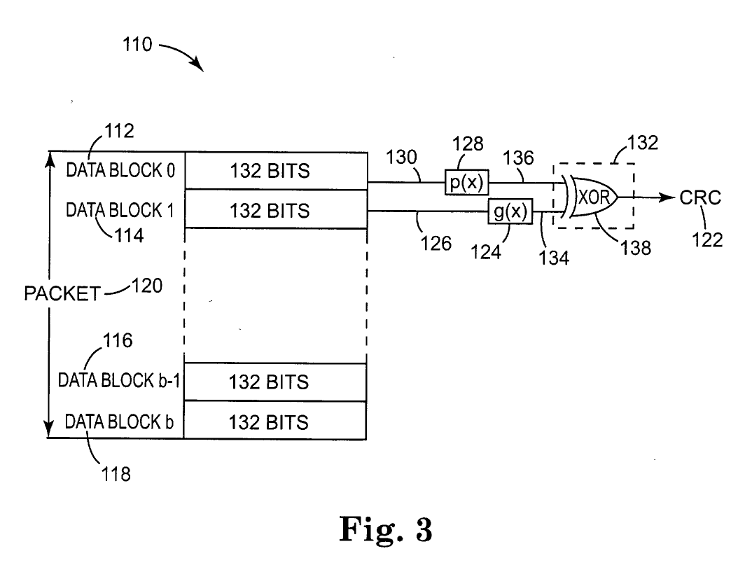

An example embodiment of a rolling CRC error detection scheme according to the present invention for generating a rolling CRC having a depth of one is illustrated generally at 110 in block diagram form in FIG. 3. In this example embodiment, an example packet 120 comprises a series of data blocks 0 indicated at 112; 1 indicated at 114; . . . ; b-1 indicated at 116; and b indicated at 118. CRC 1 indicated at 122 corresponding to data block 1 indicated at 114 is calculated as described below. The 132 bits of data block 1 indicated at 114 are received by a first CRC generator 124 via a link 126. CRC generator 124 divides data block 1 by a first generator polynomial g(x) to create a 12-bit first interim CRC. The 132 bits of data block 0 indicated at 112 are received by a second CRC generator 128 via a link 130. CRC generator 128 divides data block 0 by a second generator polynomial p(x) to create a 12-bit second interim CRC. A final CRC generator 132 receives the first interim CRC via a link 134 and the second interim CRC via a link 136, and performs a function to combine the first and second interim CRCs. In the example embodiment illustrated in FIG. 3, final CRC generator 132 performs an XOR function 138 on the first and second interim CRCs, to thereby provide the 12-bit CRC 1 indicated at 122 for data block 1 indicated at 114. Together, data block 1 indicated at 114 and CRC 1 indicated at 122 form a flit 1 similar to example flit 80 of FIG. 2B. CRCs for the other data blocks of packet 120 are produced in a similar manner as described above for CRC 1 indicated at 122. In addition, CRCs can be calculated in a similar manner as described above for other data blocks which cross a packet boundry.

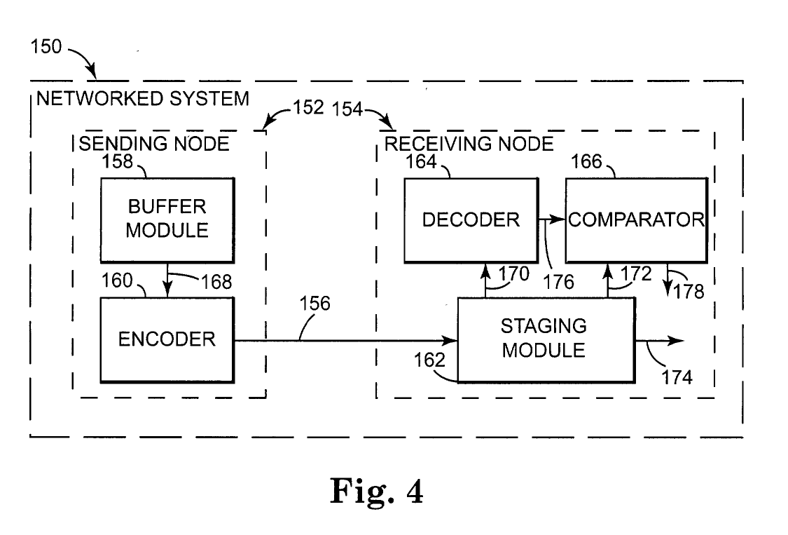

FIG. 4 is a block diagram of one embodiment of a networked system 150 according to the present invention. Networked system 150 includes a sending node 152, a receiving node 154, and a network connection 156. Sending node 152 includes a buffer module 158 and an encoder 160. Receiving node 154 includes a staging module 162, a decoder 164, and a comparator 166. Network connection 156 can be any suitable type of connection including, but not limited to, a local area network (LAN) connection; a bus connection; a telephone line/modem connection; a direct wireless connection; an internet connection; and/or an intranet connection.

Buffer module 158 receives a series of data blocks and provides them in a desired sequence to encoder 160 via a link 168. Encoder 160 receives the series of data blocks and provides for at least one data block of the series an expected CRC that is a function of the at least one data block and a preceding data block. Sending node 152 then provides the series of data blocks along with the expected CRC for the at least one data block to receiving node 154 via network connection 156.

Staging module 162 receives the series of data blocks and the expected CRC for the at least one data block via network connection 156 and provides the series of data blocks in a proper sequence to decoder 164 via a link 170 and the CRC for the at least one data block to comparator 166 via a link 172. Staging module 162 also provides the series of data blocks at an output 174 to a buffer or a process that can begin working with the data without committing to it. Decoder 164 provides to comparator 166 via a link 176 a calculated CRC for the at least one data block that is a function of the at least one data block and the preceding data block. Comparator 166 compares the calculated CRC to the expected CRC and provides at an output 178 an indication of whether a data error is present in the at least one data block or the preceding data block. In one embodiment, if the expected CRC and the calculated CRC match, output 178 indicates that the data blocks were received free of error and the process can commit to the data. In one embodiment, if the expected CRC and the calculated CRC do not match, then output 178 indicates that the at least one data block, the preceding data block, or both, have a data error and the buffer or the process can discard the data.

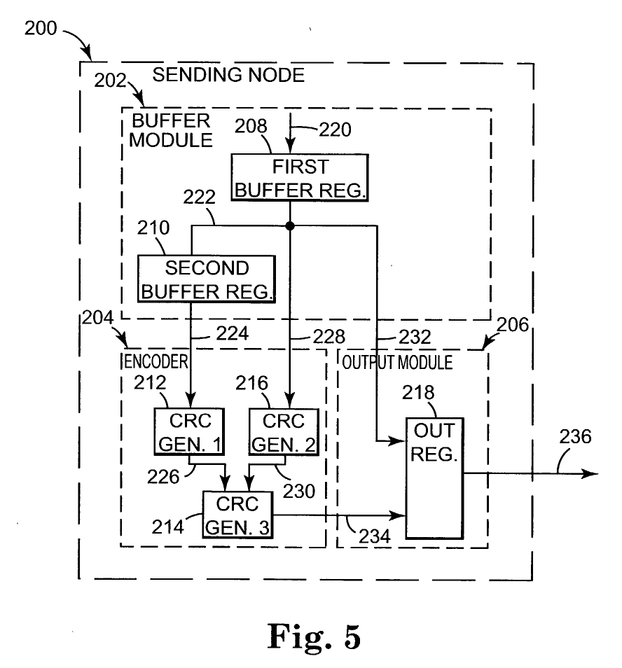

FIG. 5 is a block diagram of one embodiment of a sending node 200 having a rolling CRC error detection scheme of depth one according to the present invention. Sending node 200 comprises a buffer module 202, an encoder 204, and an output module 206. Buffer module 202 includes a first buffer register 208 and a second buffer register 210. Encoder 204 includes a first CRC generator 212, a second CRC generator 214, and a third CRC generator 216. Output module 206 includes an output register 218.

First buffer register 208 receives a series of data blocks via an input 220. As a result, second buffer register 210 receives a delayed version of the series of data blocks from first buffer register 208 via a link 222. First buffer register 220 contains the currently received data block while second buffer register 210 contains the preceding data block of the series of data blocks.

First CRC generator 212 receives the preceding data block from second buffer register 210 via a link 224, and provides a first interim CRC that is a function of the preceding data block to third CRC generator 214 via a link 226. Second CRC generator 216 receives the current data block from first buffer register via a link 228, and provides a second interim CRC that is a function of the current data block to third CRC generator 214 via a link 230. Third CRC generator 214 performs a function on the first and second interim CRCs and provides a CRC for the current data block.

Output register 218 receives the current data block from first buffer register 208 via a link 232 and the CRC for the current data block from third CRC generator 214 via a link 234 to thereby provide a flit comprising the current data block and the CRC for the current data block for transmission via a network connection 236. If a CRC of depth zero is configured into sending node 200, second buffer register 210 is reset to zero and third CRC generator 214 provides a CRC for the current data block that is a function only of the current data block.

In one embodiment, circuitry in sending node 200 is preset to the desired CRC depth. In one embodiment, a user having access to sending node 200 or an application or process running on sending node 200 selects the desired CRC depth.

In one embodiment, the function of first CRC generator 212 is to divide the preceding data block by a first primitive polynomial. In one embodiment, the function of second CRC generator 216 is to divide the current data block by a second primitive polynomial that is different from the first primitive polynomial. In one embodiment, the function of third CRC generator 214 is to XOR the first and second interim CRCs respectively received from first CRC generator 212 and second CRC generator 216.

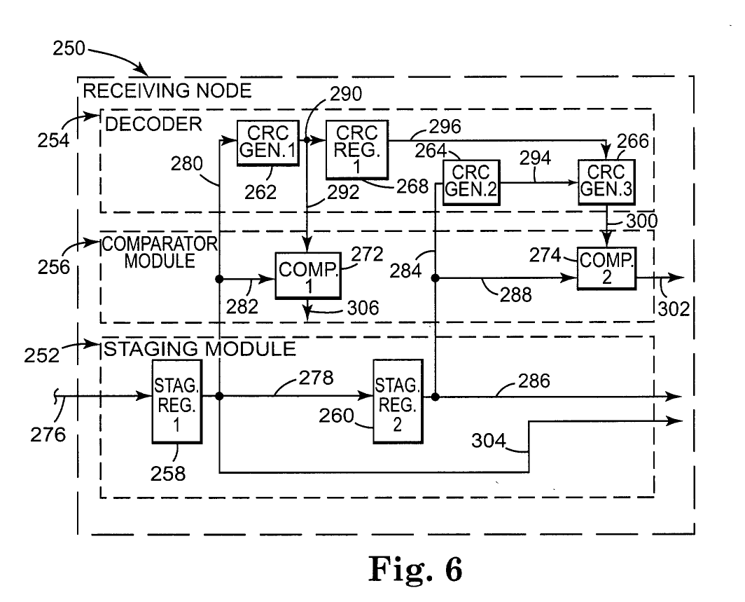

FIG. 6 is a block diagram of one embodiment of a receiving node 250 having a rolling CRC error detection scheme of depth one according to the present invention. Receiving node 250 comprises a staging module 252, a decoder 254, and a comparator module 256. Staging module 252 includes a first staging register 258 and a second staging register 260. Decoder 254 includes a first CRC generator 262, a second CRC generator 264, a third CRC generator 266, and a first CRC register 268. Comparator module 256 includes a first comparator 272 and a second comparator 274.

First staging register 258 receives a series of flits, each flit comprising a data block and an expected CRC, via a network connection 276. With receipt of each subsequent flit of the series of flits, first staging register 258 transfers the preceding flit to second staging register 260 via a link 278. As a result, first staging register 258 contains a current flit while second staging register 260 contains a preceding flit. When first staging register 258 receives the next flit of the series of flits, first staging register transfers the current flit to second staging register 260 via link 278, transfers the data block of the current flit to first CRC generator 262 via a link 280, and the expected CRC of the current flit to first comparator 272 via a link 282. When second staging register 260 receives the current flit from first staging register 258, second staging register 260 transfers the data block of the preceding flit to second CRC generator 264 via a link 284 and to a destination buffer or destination process via a link 286, and transfers the expected CRC of the preceding flit to second comparator 274 via a link 288.

First CRC generator 262 performs a function on the data block of the current flit and provides a first interim CRC to first CRC register 268 via a link 290 and to first comparator 272 via a link 292. Second CRC generator 264 performs a function on the data block of the preceding flit and provides a second interim CRC to third CRC generator 266 via a link 294. Third CRC generator 266 receives the first interim CRC from first CRC register 268 via a link 296. Third CRC generator 266 performs a function on the first and second interim CRCs and provides a calculated CRC for the data block of the current flit to second comparator 274 via a link 300. Second comparator 274 compares the expected CRC to the calculated CRC for the current flit and provides an error indication to the destination buffer or destination process via an output 302. In one embodiment, if the expected CRC matches the calculated CRC for the current flit, output 302 indicates that the current flit was received free of error and that the destination process can commit to the data block of the current flit. In one embodiment, if the expected CRC does not match the calculated CRC for the current flit, output 302 indicates that the data blocks of the current and the preceding flit are to be discarded by the destination buffer or destination process and these flits retransmitted.

FIG. 6 illustrates a rolling CRC error detection scheme of depth one. Nonetheless, any given rolling CRC error detection scheme of depth x can be configured to utilize any reduced depth (i.e., x−1, x−2, . . . , 0) by disabling later stages. This offers the flexibility of trading off latency verses reliability with the same circuitry where lower depth has less latency but less reliability.

For example, one embodiment of receiving node 250 is configured to utilize a rolling CRC of depth zero by disabling the second stage circuitry. In this zero depth configuration, upon receipt of the next flit of the series of flits, first staging register 258 bypasses second staging register 260 and provides the data block of the current flit directly to the destination buffer or destination process via a link 304. In this zero depth configuration, first comparator 272 compares the calculated CRC to the expected CRC of the current flit and provides an error indication to the destination buffer or destination process via an output 306. In one embodiment of this zero depth configuration, if the expected CRC matches the calculated CRC for the current flit, output 306 indicates that the current flit was received free of error and that the destination process can commit to the data block of the current flit. In one embodiment of this zero depth configuration, if the expected CRC does not match the calculated CRC for the current flit, output 306 indicates that the current flit is to be discarded by the destination buffer or destination process and the current flit be retransmitted.

In one embodiment, circuitry in receiving node 250 is preset to the desired CRC depth. In one embodiment, a user having access to receiving node 250 or an application or process running on receiving node 250 selects the desired CRC depth.

In one embodiment, the function of first CRC generator 262 is to divide the preceding data block by a first primitive polynomial. In one embodiment, the function of second CRC generator 264 is to divide the current data block by a second primitive polynomial that is different from the first primitive polynomial. In one embodiment, the function of third CRC generator 266 is to XOR the first and second interim CRCs received respectively from first CRC generator 262 and second CRC generator 264.

In the above described embodiments, the first primitive polynomial and the second primitive polynomial are different. In one embodiment, the first primitive polynomial and the second primitive polynomial are the same primitive polynomial, but this simplification increases the probability that random multi-bit errors will be undetected, such that the above Equation II for expressing the probability that random multi-bit errors will be undetected is no longer valid. Nevertheless, an alternative embodiment of the present invention having the first primitive polynomial the same as the second primitive polynomial changes the relative weights of the bits of a given data block which are input into the primitive polynomial to calculate the two interim CRCs with the one primitive polynomial.

In one alternative embodiment, the relative weights of the bits of the data block into the primitive polynomial are changed by shifting the bit positions into the CRC generator primitive polynomial function. In this alternative embodiment, it is preferable to avoid shifting right the data by one bit, because this one bit shift introduces a significant correlation with past CRCs as a result of CRCs being formed with cyclic shifts with module operation. One simple solution for shifting in this alternative embodiment would be to shift circular left by x bits, wherein x is greater than 1.

In another alternative embodiment, the bits of the data block used for calculating the first interim CRC are reversed for calculating the second interim CRC.

In another alternative embodiment, bits for calculating the first interim CRC are shuffled to calculate the second interim CRC (e.g., shuffle bit 0 with 1, bit 2 with 3 and so on; shuffle bit 0 with bit n, bit 1 with bit n-1, and so on; or shuffle bits 0 through 7 with bits n through n-7, bits 8 through 15 with bits n-8 through n-15, and so on). Any suitable shuffle of the bits that produces a new primitive polynomial that doesn't have the first primitive polynomial as a significant component can be used in this embodiment.

In a hybrid embodiment, different primitive polynomials are used to calculate the first and second interim CRCs and the relative weights of the input bits of the data block employed to calculate the interim CRCs are also changed by shifting or shuffling the bits.

One embodiment of the above described rolling CRC error detection scheme of the present invention provides networked systems with improved error detection capability by having the CRC of a given data block (e.g., block b) in a corresponding transmitted flit serve not only as an error check for the given data block in the corresponding flit, but also for the data blocks (e.g., block b-1 through b-x) of the one or more flits preceding the given data block in transmission through the network connection. By doing so, this embodiment of the rolling CRC error detection scheme of the present invention can provide improved error detection capability without decreasing the effective bandwidth between the sending and receiving nodes and without the latency involved with having to wait for all of the data blocks of a packet before determining whether to use the data blocks that form the packet.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiments shown and described without departing from the scope of the present invention. Those with skill in the chemical, mechanical, electro-mechanical, electrical, and computer arts will readily appreciate that the present invention may be implemented in a very wide variety of embodiments. This application is intended to cover any adaptations or variations of the preferred embodiments discussed herein. Therefore, it is manifestly intended that this invention be limited only by the claims and the equivalents thereof.

What is claimed is:

1. A sending node comprising:
an encoder configured to receive a series of data blocks and to provide for at least one data block of the series an expected cyclic redundancy code (CRC) that is a function of the at least one data block and a preceding data block.

2. The sending node of claim 1, wherein the encoder provides for at least one data block of the series an expected CRC that is a function of the at least one data block and a plurality of preceding data blocks.

3. The sending node of claim 1, wherein the encoder provides for at least one data block of the series an expected CRC that is a function of the at least one data block and a selectable number of preceding data blocks.

4. The sending node of claim 1, wherein the encoder provides for at least one data block of the series an expected CRC that is not a function of a preceding data block.

5. The sending node of claim 1 wherein the encoder further comprises:
a buffer module receiving the series of data blocks and including:
a first buffer register providing the at least one data block; and
a second buffer register receiving the at least one data block and providing the preceding block.

6. The sending node of claim 1, wherein the encoder further comprises:
a first CRC generator that receives the at least one data block and performs a function on the at least one data block to thereby provide a first interim CRC;
a second CRC generator that receives the preceding data block and performs a function on the preceding data block to thereby provide a second interim CRC; and
a third CRC generator that receives the first and second interim CRCs and performs a function on the first and second interim CRCs to thereby provide the expected CRC for the at least one data block.

7. The sending node of claim 6, wherein the function performed by the first CRC generator divides the at least one data block by a first polynomial and the function performed by the second CRC generator divides the preceding data block by a second polynomial which is different than the first polynomial.

8. The sending node of claim 6, wherein the function performed by the first CRC generator divides the at least one data block by a first polynomial and the function performed by the second CRC generator divides the preceding data block by the first polynomial.

9. The sending node of claim 6, wherein the function performed by the third CRC generator is an exclusive-OR operation on the first and second interim CRCs.

10. The sending node of claim 1, further comprising:
an output module receiving the at least one data block and the expected CRC for the at least one data block to thereby provide a flit comprising the at least one data block and the expected CRC for the at least one data block.

11. A receiving node comprising:
a decoder configured to receive a series of data blocks and an expected cyclic redundancy code (CRC) for at least one block of the series and to provide for the at least one data block a calculated CRC that is a function of the at least one data block and a preceding data block; and
a comparator configured to compare the calculated CRC to the expected CRC for the at least one data block to thereby provide an indication of whether a data error is present in the at least one data block or the preceding data block.

12. The receiving node of claim 11, wherein the decoder provides for the at least one data block of the series a calculated CRC that is a function of the at least one block and a plurality of preceding data blocks.

13. The receiving node of claim 11, wherein the decoder provides for the at least one data block of the series a calculated CRC that is a function of the at least one block and a selectable number of preceding blocks.

14. The receiving node of claim 11, wherein the decoder provides for at least one data block of the series a calculated CRC that is not a function of a preceding block.

15. The receiving node of claim 11 further comprising:
a staging module receiving the series of data blocks and the expected CRC for the at least one data block and including:
a first staging register providing the at least one data block; and
a second staging register receiving the at least one data block and providing the preceding data block and the expected CRC for the at least one data block.

16. The receiving node of claim 11, wherein the decoder further comprises:
a first CRC generator that receives the at least one data block and performs a function on the at least one data block to thereby provide a first interim CRC;
a first CRC register that receives and provides the first interim CRC;
a second CRC generator that receives that preceding data block and performs a function on the preceding block to thereby provide a second interim CRC; and
a third CRC generator that receives the first and second interim CRCs and performs a function on the first and second interim CRCs to thereby provide the calculated CRC for the at least one data block.

17. The receiving node of claim 16, wherein the function performed by the first CRC generator divides the at least one data block by a first polynomial and the function performed by the second CRC generator divides the preceding data block by a second polynomial which is different than the first polynomial.

18. The receiving node of claim 16, wherein the function performed by the first CRC generator divides the at least one data block by a first polynomial and the function performed by the second CRC generator divides the preceding data block by the first polynomial.

19. The receiving node of claim 16, wherein the function performed by the third CRC generator is an exclusive-OR operation on the first and second interim CRCs.

20. A networked system comprising:
a network connection;
a sending node coupled to the network connection and comprising:
an encoder configured to receive a series of data blocks and to provide for at least one data block of the series an expected cyclic redundancy code (CRC) that is a function of the at least one data block and a preceding data block; and
a receiving node coupled to the network connection and comprising:
a decoder configured to receive from the sending node the series of data blocks and the expected CRC for the at least one data block of the series and to provide for the at least one data block a calculated CRC that is a function of the at least one data block and the preceding data block; and
a comparator configured to compare the calculated CRC to the expected CRC for the at least one data block to thereby provide an indication of whether a data error is present in the at least one data block or the preceding data block.

21. The networked system of claim 20, wherein the encoder provides for at least one data block of the series an expected CRC that is a function of the at least one data block and a plurality of preceding data blocks, and the decoder provides for the at least one data block a calculated CRC that is a function of the at least one data block and the plurality of preceding blocks.

22. The networked system of claim 20, wherein the encoder provides for at least one data block of the series an expected CRC that is a function of the at least one data block and a selectable number of preceding data blocks, and the decoder provides for the at least one data block a calculated CRC that is a function of the at least one data block and the selectable number of preceding data blocks.

23. The networked system of claim 20, wherein the encoder provides for at least one data block of the series an expected CRC that is not a function of a preceding data block, and the decoder provides for the at least one data block a calculated CRC that is not a function of a preceding data block.

24. The networked system of claim 20, wherein the encoder further comprises:
a buffer module receiving the series of data blocks and including:
a first buffer register providing the at least one data block; and
a second buffer register receiving the at least one data block and providing the preceding block.

25. The networked system of claim 20, wherein the encoder further comprises:
a first CRC generator that receives the at least one block and performs a function on the at least one block to thereby provide a first interim CRC;
a second CRC generator that receives the preceding block and performs a function on the preceding block to thereby provide a second interim CRC; and
a third CRC generator that receives the first and second interim CRCs and performs a function on the first and second interim CRCs to thereby provide the expected CRC.

26. The networked system of claim 25, wherein the function performed by the first CRC generator divides the at least one data block by a first polynomial and the function performed by the second CRC generator divides the preceding block by a second polynomial which is different than the first polynomial.

27. The networked system of claim 25, wherein the function performed by the first CRC generator divides the at least one data block by a first polynomial and the function performed by the second CRC generator divides the preceding data block by the first polynomial.

28. The networked system of claim 25, wherein the function performed by the third CRC generator is an exclusive-OR operation on the first and second interim CRCs.

29. The networked system of claim 20, wherein the sending node further comprises:
an output module receiving the at least one data block and the expected CRC for the at least one data block to thereby provide a flit comprising the at least one data block and the expected CRC for the at least one data block.

30. The networked system of claim 20, wherein the receiving node further comprises:
a staging module receiving the series of data blocks and the expected CRC for the at least one data block and including:
a first staging register providing the at least one data block; and
a second staging register receiving the at least one data block and providing the preceding data block and the expected CRC for the at least one data block.

31. The networked system of claim 20, wherein the decoder further comprises:
a first CRC generator that receives the at least one data block and performs a function on the at least one data block to thereby provide a first interim CRC;
a first CRC register that receives and provides the first interim CRC;
a second CRC generator that receives the preceding data block and performs a function on the preceding data block to thereby provide a second interim CRC; and
a third CRC generator that receives the first and second interim CRCs and performs a function on the first and second interim CRCs to thereby provide the calculated CRC for the at least one data block.

32. The networked system of claim 31, wherein the function performed by the first CRC generator divides the at least one data block by a first polynomial and the function performed by the second CRC generator divides the preceding data block by a second polynomial which is different than the first polynomial.

33. The networked system of claim 31, wherein the function performed by the first CRC generator divides the at least one data block by a first polynomial and the function performed by the second CRC generator divides the preceding data block by the first polynomial.

34. The networked system of claim 31, wherein the function provided by the third CRC generator is an exclusive-OR operation on the first and second interim CRCs.

35. A transmitter comprising:
an encoder configured to receive a series of data blocks and to provide for at least one data block of the series an expected cyclic redundancy code (CRC) that is a function of the at least one data block and a preceding data block.

36. The transmitter of claim 35, wherein the encoder provides for at least one data block of the series an expected CRC that is a function of the at least one data block and a plurality of preceding data blocks.

37. The transmitter of claim 35, wherein the encoder provides for at least one data block of the series an expected CRC that is a function of the at least one data block and a selectable number of preceding data blocks.

38. The transmitter of claim 35, wherein the encoder provides for at least one data block of the series an expected CRC that is not a function of a preceding data block.

39. A receiver comprising:
a decoder configured to receive a series of data blocks and an expected cyclic redundancy code (CRC) for at least one block of the series and to provide for the at least one data block a calculated CRC that is a function of the at least one data block and a preceding data block; and
a comparator configured to compare the calculated CRC to the expected CRC for the at least one data block to thereby provide indication of whether a data error is present in the at least one data block or the preceding data block.

40. The receiving node of claim 39, wherein the decoder provides for the at least one data block of the series a calculated CRC that is a function of the at least one block and a plurality of preceding data blocks.

41. The receiving node of claim 39, wherein the decoder provides for the at least one data block of the series a calculated CRC that is a function of the at least one block and a selectable number of preceding blocks.

42. The receiving node of claim 39, wherein the decoder provides for at least one data block of the series a calculated CRC that is not a function of a preceding block.

43. A method of communicating data, the method comprising:
generating a cyclic redundancy code (CRC) for at least one data block of a series of data blocks, wherein the CRC is a function of the at least one data block and a preceding data block.

44. The method of claim 43 further comprising:
wherein the generating of the CRC comprises generating the CRC as an expected CRC for the at least one block at a sending node.

45. The method of claim 44 further comprising:
combining the at least one data block and the expected CRC for the at least one data block at the sending node to thereby provide a flit comprising the at least one data block and the expected CRC for the at least one data block;
receiving the flit at a receiving node;
generating at the receiving node a calculated CRC for the at least one data block, wherein the calculated CRC is a function of the at least one data block and the preceding data block; and
comparing, at the receiving node, the calculated CRC to the expected CRC for the at least on data block to thereby provide an indication of whether a data error is present in the at least one data block or the preceding data block.

46. The method of claim 43 further comprising:
wherein the generating of the CRC comprises generating the CRC as a calculated CRC for the at least one data block at a receiving node;
receiving, at the receiving node, the series of data blocks and an expected CRC for the at least one data block; and
comparing, at the receiving node, the calculated CRC to the expected CRC for the at least on data block to thereby provide an indication of whether a data error is present in the at least one data block or the preceding data block.

47. The method of claim 43 wherein the CRC is a function of the at least one data block and a plurality of preceding data blocks.

48. The method of claim 43 wherein the CRC is a function of the at least one data block and a selectable number of preceding data blocks.

49. The method of claim 43 further comprising:
generating a second CRC for at least one data block of the series of data blocks, wherein the second CRC is a not a function of a preceding data block.
